(19) United States
(12) Patent Application Publication
(10) Pub. No.: US 2025/0374715 A1
(43) Pub. Date: Dec. 4, 2025

(54) OPTOELECTRONIC DEVICE AND MANUFACTURING METHOD THEREOF

(71) Applicant: ALEDIA, Champagnier (FR)

(72) Inventor: Eric POURQUIER, Saint Jean De Vedas (FR)

(73) Assignee: ALEDIA, Champagnier (FR)

(21) Appl. No.: 19/223,118

(22) Filed: May 30, 2025

(30) Foreign Application Priority Data
May 30, 2024 (FR) FR2405604

(51) Int. Cl. H10H 20/816; H10H 20/01

(52) U.S. Cl. CPC H10H 20/8162; H10H 20/017; H10H 20/032; H10H 20/0364

(57) ABSTRACT

One or more embodiments relate to a light-emitting diode including at least one three-dimensional structure including: a first part having a first conductivity, a second part having a second conductivity, an active region configured to emit a light radiation, interposed between the first part and the second part, the diode also including: a first electrical contact configured to inject carriers into the first part, a second electrical contact configured to inject carriers into the second part. The diode includes a deceleration layer interposed between the first contact and the first part, configured to decelerate the carriers obtained from the first contact before being injected into the first part.

### TECHNICAL FIELD

The present invention relates to the field of optoelectronics. The invention is particularly advantageous for the manufacture of optoelectronic devices having a three-dimensional (3D) structure, for example light-emitting diodes based on nanowires.

### PRIOR ART

A light-emitting diode (LED) typically comprises regions for injecting carriers (electrons and holes) between which an active region is interposed. The active region is the location where radiative electron-hole pair recombinations, which make it possible to obtain a light emission, take place. This active region can in particular comprise quantum wells, for example based on InGaN.

LEDs having a three-dimensional structure (3D LEDs), typically in the form of nanowires or pyramids, can have different architectures, particularly in terms of the arrangement of the different constituent regions of the LED.

These different regions can be disposed in a stack along a longitudinal direction z. Such an LED architecture is referred to as axial. An axial 3D LED typically has, in a stack along z, a bottom part bearing on a substrate, an active region bearing on the bottom part, and a top part bearing on the active region. The bottom part is generally intended for injecting electrons and the top part for injecting holes. The active region typically has quantum wells extending transversely to the longitudinal direction z.

Alternatively, the different regions of the LED can be disposed radially around the longitudinal direction z. Such an LED architecture is referred to as radial or core-shell. A radial 3D LED typically has an elongated inner part (the core) along z and bearing on a substrate, an active region surrounding the inner part, and an outer part (the shell) surrounding the active region. The inner part is generally intended for injecting electrons and the outer part for injecting holes. The active region typically has quantum wells extending parallel to the longitudinal direction z.

To improve the radiative recombination rate, i.e. the external quantum efficiency (EQE) of LEDs, an existing solution is to confine carriers within the active region by adding one or more carrier blocking layers around the active region.

In particular, an electron blocking layer (EBL) can be added between the hole injection region and the active region. This EBL layer prevents electrons from the electron injection region from passing through the active region without being recombined. The EBL layer is configured to block electrons and allow holes to pass.

In a corollary manner, a hole blocking layer (HBL) can be added between the electron injection region and the active region. This HBL layer prevents holes from the hole injection region from passing through the active region without being recombined. The HBL layer is configured to block the holes and allow the electrons to pass.

In practice, the introduction of these EBL and/or HBL layers gives rise to other problems, particularly the appearance of structural defects, the appearance of electrical series resistances and/or an undesirable deceleration of the carriers that must pass through these layers. From a technological point of view, the formation of EBL and/or HBL layers in 3D LED architectures is not sufficiently controlled.

There is therefore a need to design a 3D LED architecture with an enhanced EQE. The present invention aims to meet this need and/or at least partially overcome the aforementioned drawbacks.

In particular, an object of the present invention is that of providing a light-emitting diode with a radial or axial 3D structure, having an optimized EQE. Another object of the present invention is that of providing a method for manufacturing such a light-emitting diode.

The other objects, features and advantages of the present invention will be clear after an examination of the following description and the accompanying drawings. It is understood that other advantages can be incorporated. In particular, certain features and certain advantages of the device may apply mutatis mutandis to the method, and vice versa.

### SUMMARY

In order to achieve the objectives mentioned above, a first aspect of the invention relates to a light-emitting diode comprising at least one three-dimensional structure (3D) comprising:
a first part having a first conductivity of a first carrier type,
a second part having a second conductivity of a second carrier type,
an active region configured to emit or receive a light radiation of wavelength λ, said active region being interposed between the first part and the second part.

The diode further comprises:
a first electrically conducting contact configured to inject carriers of the first type into the first part,
a second electrically conducting contact configured to inject carriers of the second type into the second part.

Advantageously, the light-emitting diode comprises a carrier deceleration layer interposed between the first contact and the first part of the 3D structure. This deceleration layer is configured to decelerate the carriers of the first type from the first contact before being injected into the first part.

Within the scope of the development of the present invention, it was observed that the efficiency of LEDs is decreased by the very great difference in velocities between electrons and holes. This difference limits recombination possibilities. Electrons can pass through the active region rapidly without encountering holes. A means of decelerating electrons was therefore developed.

Thus, the first part and the first contact are not in direct contact with each other. The deceleration layer is an intermediate layer providing an ohmic contact between the first contact and the first part of the 3D structure. The carriers of the first type are typically electrons. The first part of the 3D structure is typically based on GaN-n. The deceleration layer can be based on a diluted magnetic semiconductor (DMS) material, for example based on cobalt-doped ZnO.

The DMS material typically induces a change in the trajectory of the electrons transported to the first part made of GaN-n. This alteration of the electron trajectory can result from an interaction between the electron spins and the spin-orbits of the ferromagnetic atoms of the DMS material.

The DMS material advantageously makes it possible to inject the electrons into the first part made of GaN-n, along random or disorganized trajectories. In particular, the electron trajectories have a component perpendicular to the electric field. The apparent electron mobility is therefore reduced.

This lower electron mobility is maintained in the first part of the 3D structure up to the electron/hole recombination zones, in the active region. This promotes radiative recombinations between electrons and holes. The EQE efficiency of the LED is enhanced.

This electron deceleration effect is all the more pronounced and persistent as the deceleration layer is disposed in the vicinity of the active region, in the 3D structure according to the present invention. The benefit of deceleration is thus maximized. This is particularly advantageous for increasing the radiative recombination rate between electrons and holes in the active region of an LED with a 3D structure according to the present invention.

A second aspect of the invention relates to a method for manufacturing a light-emitting diode according to the first aspect. This method particularly comprises the following steps:
forming the first part by epitaxy on a growth substrate, by localized growth through an opening of a masking layer disposed on said growth substrate,
forming the active region by epitaxy on the first part,
forming the second part by epitaxy on the active region, then
forming the second contact on the second part, by depositing a transparent conducting oxide layer,
depositing a planarization layer on the growth substrate, on and around the at least one 3D structure protruding from the growth substrate, so as to obtain a planar surface above the at least one 3D structure,
bonding a handling substrate on said planar surface,
removing the growth substrate so as to expose a portion of the first part through the masking layer,
forming the deceleration layer in contact with the exposed portion of the first part,
forming the first contact on the deceleration layer.

### BRIEF DESCRIPTION OF THE DRAWINGS

The aims, objects, as well as the features and advantages of the invention will appear better from the detailed description of embodiments thereof which are illustrated by the following accompanying drawings, wherein:

FIG. 1 illustrates a radial 3D LED comprising an electron deceleration layer, according to one embodiment of the present invention.

FIGS. 2 to 13 schematically illustrate different steps of a method for producing a 3D LED with an electron deceleration layer, according to one embodiment of the present invention.

FIG. 14 schematically illustrates an alternative embodiment of the first contact of the 3D LED, according to one embodiment of the present invention.

The drawings are given as examples and do not limit the invention. They constitute schematic outline representations intended to facilitate understanding of the invention and are not necessarily plotted to the scale of practical applications. In particular, the dimensions of the different layers and the different parts of the 3D LED do not necessarily represent reality.

### DETAILED DESCRIPTION

Before starting a detailed review of embodiments of the invention, it should be recalled that the invention according to its first aspect particularly comprises the optional features hereinafter which could be used in combination or alternatively:

According to one example, the carriers of the first type are electrons and the first conductivity is N-type, the carriers of the second type are holes and the second conductivity is P-type, and the deceleration layer is an electron deceleration layer based on a diluted magnetic semiconductor material.

According to one example, the diluted magnetic semiconductor material is based on ZnO doped with at least one element taken from cobalt (Co), manganese (Mn), niobium (Nb), chromium (Cr), iron (Fe), nickel (Ni), neodymium (Nd).

According to one example, the 3D LED further comprises a masking layer having a so-called bottom face, a so-called top face, and openings. According to one example, the first part passes through the masking layer at said openings, up to the deceleration layer, the deceleration layer being in contact with the bottom face of the masking layer. This structural feature of the 3D LED is typically associated with a localized SAG (Selective Area Growth) 3D structure growth method. The presence of the masking layer is generally a residual element of the implementation of localized SAG growth. Such a masking layer is not present in so-called planar 2D LEDs. Mesa-structured LEDs by planar layer etching, according to a technological approach referred to as “top-down”, do not have a masking layer. The masking layer is generally specific to the implementation of an SAG method for 3D structure formation, according to a technological approach referred to as “bottom-up”. The presence of the masking layer is a means for differentiating between “bottom-up” 3D LEDs and “top-down” LEDs obtained from planar technologies. According to one possibility, the first part bears on the top face of the masking layer. According to one example, the three-dimensional structure is obtained by localized growth through the openings of the masking layer. The openings of the masking layer can be distributed evenly in the form of a lattice. A portion at the base of the first part of the 3D structure is typically enclosed by the masking layer. The first part can furthermore expand above the enclosed portion, and bear on the masking layer.

According to one example, the 3D structure has a so-called radial architecture such that:
the first part extends mainly along a direction z, and has edges substantially parallel to the direction z and a vertex substantially perpendicular to the direction z,
the active region comprises a so-called radial part covering the edges of the first part, and a so-called vertex part covering the vertex of the first part,
the second part covers the radial part and the vertex part of the active region.

According to one example, the radial part forms at least 80% of the active region.

According to one example, the deceleration layer extends transversely to said radial part.

According to one example, the first part and the deceleration layer have a common interface which extends in a plane substantially perpendicular to the direction z.

According to an alternative example, the 3D structure has a so-called axial architecture forming a stack along a direction z such that:
the first part has edges substantially parallel to the direction z and a vertex substantially perpendicular to the direction z,
the active region covers only the vertex of the first part, and has edges substantially parallel to the direction z plumb with the edges of the first part, and a vertex substantially perpendicular to the direction z,
the second part covers only the vertex of the active region, and has edges substantially parallel to the direction z plumb with the edges of the active region.

According to one example, the edges of the first part, the edges of the active region and the edges of the second part extend substantially plumb with each other. According to one example, these edges are oriented along m {10-10} crystallographic planes.

According to one example, the 3D LED further comprises a blocking layer of the first carrier type interposed between the second part and the active region. A synergistic effect between the deceleration of the carriers due to the deceleration layer, on one hand, and the blocking of the carriers due to the blocking layer, on the other, can thus be obtained.

According to one example, the first and second parts are based on GaN, and the active region comprises quantum wells based on InGaN.

According to one example, the handling substrate is based on a transparent material at the wavelength λ. The handling substrate can thus be retained at the end of the method. Alternatively, the handling substrate can be removed at the end of the method, typically when the handling substrate is based on an opaque material such as silicon.

According to one example, the deceleration layer is structured in the form of a pad, and the first contact is formed on and around said pad, bearing on a bottom face of the masking layer. In particular, when the LED comprises a plurality of 3D structures, each 3D structure can be contacted individually via the pads.

According to one example, the method further comprises, after forming the deceleration layer, a deposition of a dielectric layer on the deceleration layer, then an etching of a via through the dielectric layer opening onto a face of the deceleration layer, and the formation of the first contact through said via.

According to one example, the formations of the first and second parts, and the formation of the active region, are performed by metalorganic vapor-phase epitaxy (MOVPE). According to one example, the first part, the active region, and the second part are in an epitaxial relationship with each other.

According to one example, the at least one light-emitting diode comprises a plurality of light-emitting diodes, and the formation of the first parts is such that two first adjacent parts are separated from each other by a separation distance of less than 180 nm, preferably less than or equal to 100 nm. The first parts of the diodes are thus distributed along the substrate with a high surface density. This promotes axial growth of the parts above each first part, particularly the active regions.

Unless incompatible, technical features described in detail for a given embodiment may be combined with the technical features described in the context of other embodiments described for exemplary and non-limiting purposes, so as to form another embodiment which is not necessarily illustrated or described. Of course, such an embodiment is not excluded from the invention.

In the present invention, the device and the method relate in particular to an architecture and the manufacture of light-emitting diodes (LEDs) with a 3D structure. The invention can be implemented more broadly for different optoelectronic devices with a 3D structure. The invention can therefore also be implemented in the context of laser or photovoltaic devices. In the present patent application, the terms “light-emitting diode”, “LED” or simply “diode” are used as synonyms. An “LED” may also be understood as a “micro-LED”.

In the present invention, the deceleration layer is preferably based on a diluted magnetic semiconductor material. Such a material is typically obtained by introducing magnetic impurities into a semiconductor. The electronic and magnetic properties of this material are then strongly coupled.

Among the examples of diluted magnetic semiconductor material, mention can be made of II-VI semiconductors, for example ZnO, comprising a magnetic impurity, for example manganese or cobalt or nickel-substituting zinc.

Unless explicitly stated otherwise, it is specified that, in the context of the present invention, the relative arrangement of a third layer interposed between a first layer and a second layer, does not necessarily mean that the layers are directly in contact with one another, but means that the third layer is either directly in contact with the first and second layers, or separated from these by at least one other layer or at least one other element.

Thus, the terms and expressions “bear” and “cover” do not necessarily mean “in contact with”. Typically, the second part bears on the active region either directly or indirectly, for example via an interposed electron blocking layer. The active region can bear on the first part either directly or indirectly, for example via an interposed quantum barrier.

The LEDs according to the present invention are preferably based on III-V materials, particularly based on GaN. The different parts and regions of the LED typically have a hexagonal crystallographic structure. According to the Miller-Bravais system, (hkil) will be used to annotate a plane of the hexagonal structure, {hkil} a family of planes of the hexagonal structure, [hkil] a direction or a vector of the hexagonal structure.

The external quantum efficiency EQE can be broken down into three components:
The injection efficiency (IE) of the carriers in the active region,
The internal quantum efficiency (IQE) which is the ratio between the number of radiative recombinations and the total number of recombinations,
The light extraction efficiency (LEE) which corresponds to the proportion of photons coming out of the LED relative to the number of photons generated.

The term “3D structure” is understood as distinct from so-called planar or 2D structures, which have two dimensions in a plane that are substantially greater than the third dimension normal to the plane. Thus, the usual 3D structures targeted in the field of 3D LEDs can be in wire, nanowire or microwire form. Such a 3D structure has an elongated shape along the longitudinal direction. The longitudinal dimension of the wire, along z in the figures, is greater, and preferably substantially greater, than the transverse dimensions of the wire, in the plane xy in the figures. The longitudinal dimension is for example at least twice, and preferably at least ten times, greater than the transverse dimensions, preferably between three times and five times the transverse dimensions. In the example of pyramids, the ratios of longitudinal dimensions to transverse dimensions can be fixed. This typically depends on the geometries of the GaN crystals. For example, for a pyramid, the ratio of the longitudinal dimension to a transverse dimension is substantially less than or equal to 0.9. 3D structures can also be in the form of walls. In this case, only one transverse dimension of the wall is substantially less than the other dimensions, for example three to five times less than the other dimensions. The 3D structures of the present application preferably have substantially vertical walls or edges. The vertical walls typically extend along m {10-10} type crystallographic planes. They can be involved in a so-called radial growth mechanism. The 3D structures of the present application preferably have bases and vertices comprising substantially horizontal surfaces. These horizontal surfaces typically extend along c (0001) or −c (000-1) type crystallographic planes. They can be involved in a so-called axial growth mechanism. According to one possibility, the 3D structures are in the form of pyramids or nanopyramids. According to another possibility, the 3D structures are in the form of “elongated” pyramids or in “pencil” form, typically a nanowire topped by a pyramid.

“Axial growth” means anisotropic growth occurring essentially or only along the longitudinal direction z. “Radial growth” means isotropic growth covering particularly the surfaces parallel to the longitudinal direction z.

The steps of the method as claimed should be understood in the broad sense and can optionally be implemented in several sub-steps.

A substrate, a layer or a device, “based on” a material M is taken to mean a substrate, a layer or a device comprising only this material M or this material M and optionally other materials, for example alloying elements, impurities or doping elements.

Hereinafter, the following abbreviations relating to a material M are optionally used:
a-M refers to the material M in amorphous form, according to the terminology normally used in the microelectronic field for the prefix a-.
p-M refers to the material M in polycrystalline form, according to the terminology normally used in the microelectronic field for the prefix p-.
Similarly, the following abbreviations relating to a material M are optionally used:
M-i refers to the intrinsic or unintentionally doped material M, according to the terminology normally used in the microelectronic field for the suffix -i.
M-n refers to the N, N+ or N++ doped material M, according to the terminology normally used in the microelectronic field for the suffix -n.
M-p refers to the P, P or P++ doped material M, according to the terminology normally used in the microelectronic field for the suffix -p.

A reference frame, preferably orthonormal, comprising the axes x, y, z is shown in certain appended figures. This reference frame can be applied by extension to the other appended figures. The axis z is here parallel to the axis c, i.e. to the crystallographic direction [0001].

In the present patent application, thickness will preferentially be spoken of for a layer and height for a structure or a device. The thickness is considered along a direction normal to the main extension plane of the layer, and the height is considered perpendicularly to the base plane xy of the substrate. Thus, a layer typically has a thickness along z, when it extends mainly along a plane xy, and an LED has a height along z. The relative terms “on”, “under”, “subjacent” refer to positions taken along the direction z.

The dimensional values should be understood considering the manufacturing and measurement tolerances. The terms “substantially”, “about”, “of the order of” mean, when they relate to a value, “to within 10%” of this value or, when they relate to an angular orientation, “to within 10°” of this orientation. Thus a direction substantially normal to a plane means a direction having an angle of 90±10° with respect to the plane.

A region, a part or a layer formed by axial growth typically has substantially the same diameter, taken in a plane XY, as the region, part or layer on which it bears.

When the LED is in the form of a nanowire or a microwire, a person skilled in the art is perfectly able to differentiate between an axial architecture and a radial architecture.

To determine the geometry of the 3D structures and the compositions of the various elements (wire, active region, deceleration layer) of these 3D structures, scanning electron microscopy (SEM) or transmission electronic microscopy (TEM) or scanning transmission electron microscopy (STEM) analyses can be carried out.

TEM or STEM lend themselves particularly well to observing and identifying quantum wells—the thickness of which is generally of the order of a few nanometers—in the active region. Various techniques listed below non-exhaustively can be implemented: dark field and bright field imaging, weak beam imaging, high angle annular dark field (HAADF) imaging.

The chemical compositions of the various elements can be determined by means of the well-known EDX or X-EDS method, which means “energy dispersive x-ray spectroscopy”.

This method is well adapted to analyzing the composition of small-sized optoelectronic devices such as 3D LEDs. It can be implemented on metallurgical sections in a scanning electron microscope (SEM) or on thin plates in a transmission electron microscope (TEM).

The techniques mentioned above particularly make it possible to determine whether an optoelectronic device with a 3D structure comprises a deceleration layer within the meaning of the present invention, and/or a masking layer indicating an implementation of localized growth, as described in the present invention.

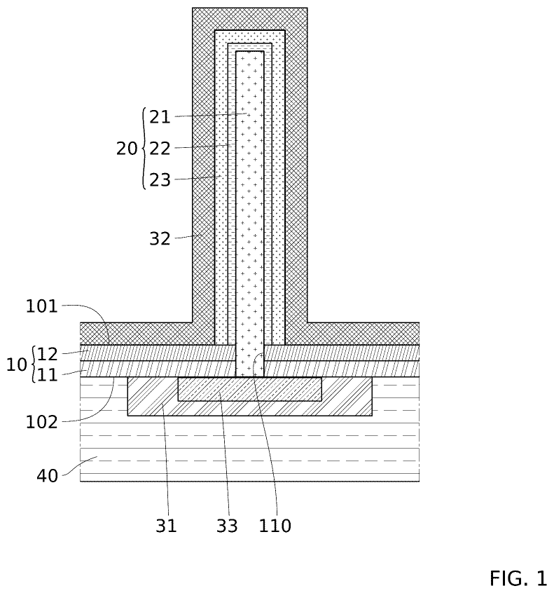

FIG. 1 illustrates an LED comprising a 3D structure 20 in nanowire form, according to one embodiment of the invention. The 3D structure 20 of the LED here has a radial architecture also referred to as core-shell. Such a radial architecture can particularly comprise, from the inside to the outside of the nanowire along the direction y:
A first part 21 having a diameter between 50 nm and 1.2 μm, typically of the order of 700 nm. This first part 21 forms the core of the nanowire. It is preferably composed of GaN-n.
An active region 22 with a thickness between 20 nm and 250 nm, typically of the order of 40 nm. The active region 22 covers the edges and the vertex of the first part 21. It is preferably composed of InGaN. The active region 22 preferably comprises InGaN-i quantum wells alternating with GaN-i quantum barriers. The quantum barriers can contain indium and/or aluminum. The quantum wells can have a thickness between 1 nm and 15 nm and the quantum barriers can have a thickness between 3 nm and 20 nm. The active region 22 is configured to emit light radiation of wavelength λ.
Optionally only, an electron blocking layer (EBL) with a thickness between 10 nm and 100 nm, typically 30 nm. The EBL layer is preferably composed of AlGaN. Such an EBL layer is not shown in FIG. 1.
A second part 23 with a thickness between 20 nm and 500 nm, typically of the order of 100 nm. The second part 23 covers the edges and the vertex of the active region 22. It is preferably composed of GaN-p.

The LED typically comprises a masking layer 10 implemented during the nanowire growth method. This masking layer 10 can comprise several sublayers, for example a layer 11 based on silicon nitride and a layer 12 based on oxide. The masking layer 10 comprises openings 110 configured to promote local growth of the nanowires. During growth, the first part 21 typically passes through the masking layer 10 at an opening 110, then extends essentially along z. According to one possibility not illustrated, the cross-section in the plane xy of the first part 21 suddenly increases at the exit of the opening 110. The first part 21 can thus bear on the top face 101 of the masking layer 10.

The LED also comprises a first electrically conducting contact 31, configured to inject charge carriers into the first part 21. In the example illustrated, the charge carriers injected by the first contact 31 are electrons. The first contact 31 can be metallic, for example based on aluminum. Advantageously, this first contact 31 can also be used as an optical reflector, to reflect the light emitted by the active region 22 on the vertex side of the nanowire (i.e. on the “front face” side of the device). This makes it possible to enhance the light extraction efficiency of the LED. The first contact 31 is typically electrically insulated by a dielectric layer 40, for example based on silicon oxide, located on the bottom face 102 around the first contact 31.

The LED also comprises a second electrically conducting contact 32, configured to inject charge carriers into the second part 23. In the example illustrated, the charge carriers injected by the second contact 32 are holes. The second contact 32 is typically transparent at the wavelength of the light emitted by the active region 22. The second contact 32 is for example based on transparent conducting oxide (TCO), for example based on ITO (indium tin oxide). Alternatively, it can be based on zinc oxide doped with gallium (GZO) or aluminum (AZO).

According to a principle of the present invention, the 3D LED advantageously comprises a deceleration layer 33 interposed between the first contact 31 and the first part 21. This deceleration layer 33 is typically based on a diluted magnetic semiconductor material, for example based on cobalt-doped ZnO. The transparency of the ZnO is not affected by cobalt doping. This material can furthermore be readily deposited and structured to form the deceleration layer 33 at the base of the nanowire.

During the operation of the LED, the electrons are decelerated by the deceleration layer 33 before reaching the first part 21. In particular, the spin interactions between the electrons and the ferromagnetic atoms of the deceleration layer 33 modify the electron trajectories. The electrons follow randomly oriented trajectories when they enter the first part 21. The electrons are both decelerated and distributed along the entire height of the nanowire. This advantageously makes it possible to promote carrier recombinations in the vertical parts of the active region 22, and to limit carrier recombinations in the vertex part of the active region 22. The radiative recombination rate is higher in m-planes than in c-planes. The EQE is enhanced, both by a deceleration effect (the likelihood of a hole being recombined with an electron increases) and by a distribution effect in m-planes (the likelihood of a recombination being radiative increases).

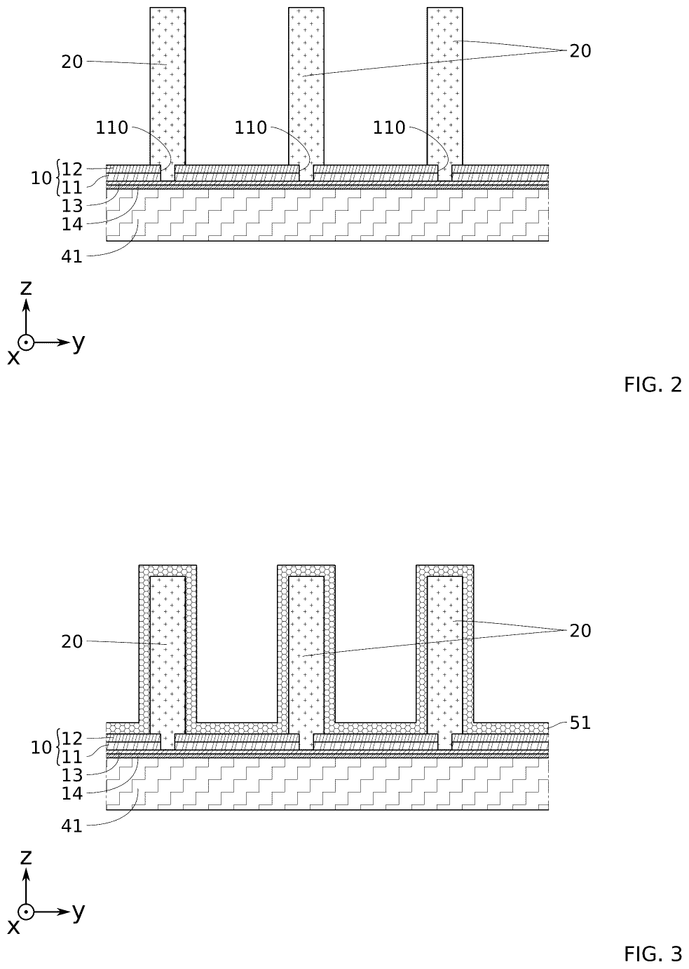

FIGS. 2 to 13 illustrate different steps of a method for producing a 3D LED structure 20 comprising a deceleration layer 33 as described above.

Hereinafter, the 3D structures 20 are presented in nanowire form. The internal architecture of these 3D structures 20 is not detailed. It can be radial as illustrated and described above. According to one alternative possibility, the 3D structures 20 have an “axial” internal architecture. In this case, in a manner known to a person skilled in the art, the first part 21 based on GaN-n, the active region 22 based on InGaN-i, optionally the electron blocking layer based on AlGaN, and the second part 23 based on GaN-p are stacked on top of each other along z.

As illustrated in FIG. 2, the nanowires 20 are firstly formed on a growth substrate 41. The substrate 41 can be based on silicon and serve as a support. The substrate 41 typically bears one or more layers 13, 14 based on or made of III-V materials, typically based on metal element nitride or carbide. A superficial layer 13, referred to as nucleation layer, makes it possible to grow the nanowires 20. The nucleation layer 13 is preferably based on AlN. Alternatively, it can be based on other metal nitrides, for example GaN or AlGaN. It can be formed on the silicon support 41 by epitaxy, preferably by metalorganic vapor-phase epitaxy (MOVPE). It advantageously has a thickness less than or equal to 200 nm, preferably less than or equal to 100 nm, for example of the order of 50 nm.

A masking layer 10 is preferably formed on the nucleation layer 13. It can comprise a plurality of sublayers based on dielectric material, for example made of silicon nitride Si3N4 and/or silicon oxide. The masking layer 10 can be formed by chemical vapor deposition (CVD). It partially masks the nucleation layer 13 and comprises preferably circular openings 110 exposing areas of the nucleation layer 13. These openings 110 typically have a dimension, for example a diameter, between 30 nm and 500 nm. The openings 110 can be evenly distributed within the masking layer 10, for example in the form of an organized lattice.

Such a masking layer 10 allows localized growth of a 3D structure 20 at each opening 110. In particular, during a preliminary growth step referred to as germination, a seed based on GaN forms at the opening 110 then fills said opening 110. Subsequent growth of the nanowire 20 then occurs from this seed, locally.

During the formation of the nanowires 20, the first parts 21, the active regions 22 and the second parts 23, are successively formed by epitaxy, preferably by metalorganic vapor-phase epitaxy MOVPE. The nanowires 20 typically have a characteristic diameter or dimension in the plane xy between 20 nm and 1500 nm, preferably between 20 nm and 500 nm. The nanowires 20 preferably have a substantially horizontal vertex, formed by a polar (0001) c-plane. They have substantially vertical edges, formed by non-polar {10-10} m-planes.

As illustrated in FIG. 3, after formation of the nanowires 20 by localized growth through the masking layer 10, a dielectric layer 51 is deposited in a conformal manner on the nanowires 20 and on the exposed parts of the masking layer 10. The dielectric layer 51 is for example based on SiO2. It can be formed by plasma-enhanced chemical vapor deposition (PECVD).

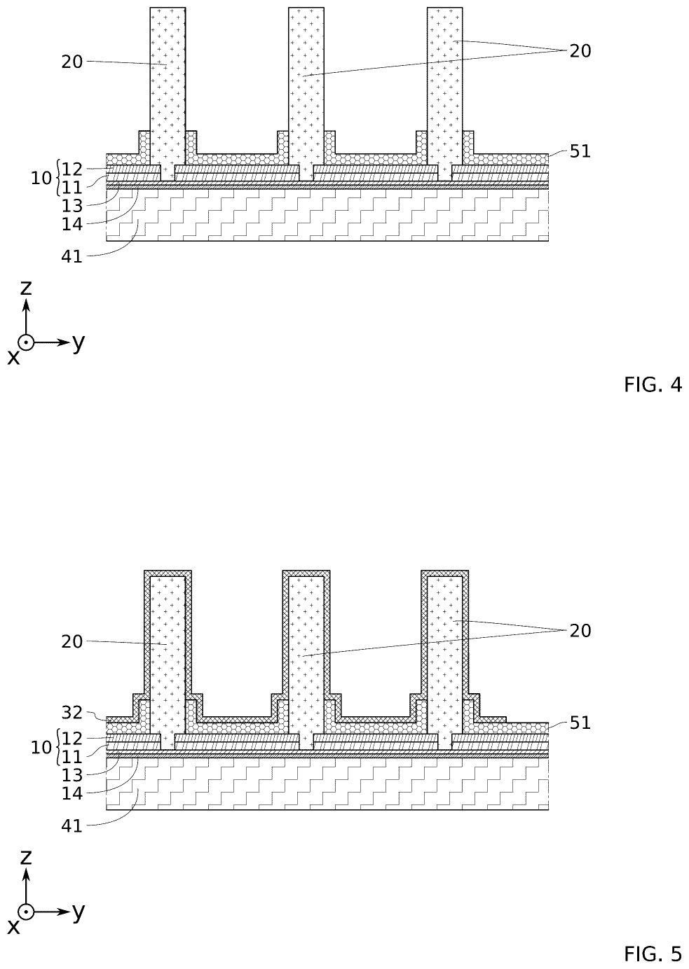

As illustrated in FIG. 4, the dielectric layer 51 is then etched in part, so as to expose the vertices and edges of the nanowires 20 along almost all of their height. The etching typically corresponds to isotropic wet etching. After etching, the dielectric layer 51 is retained on the masking layer 10. It preferably forms a ring at the base of the nanowires 20. It makes it possible to reinforce the electrical insulation provided in part by the masking layer 10.

As illustrated in FIG. 5, in particular when the nanowires 20 have a radial architecture, a layer based on a transparent electrically conducting material is deposited continuously on and between the nanowires 20. This continuous layer here completely covers the exposed vertices and edges of the nanowires 20. It makes it possible to form the second electrical contact 32. It is typically based on a transparent conducting oxide, for example based on ITO, AZO or GZO. High-temperature annealing can be performed so as to obtain an ohmic contact between the second electrical contact 32 and the second part 23 of each nanowire 20.

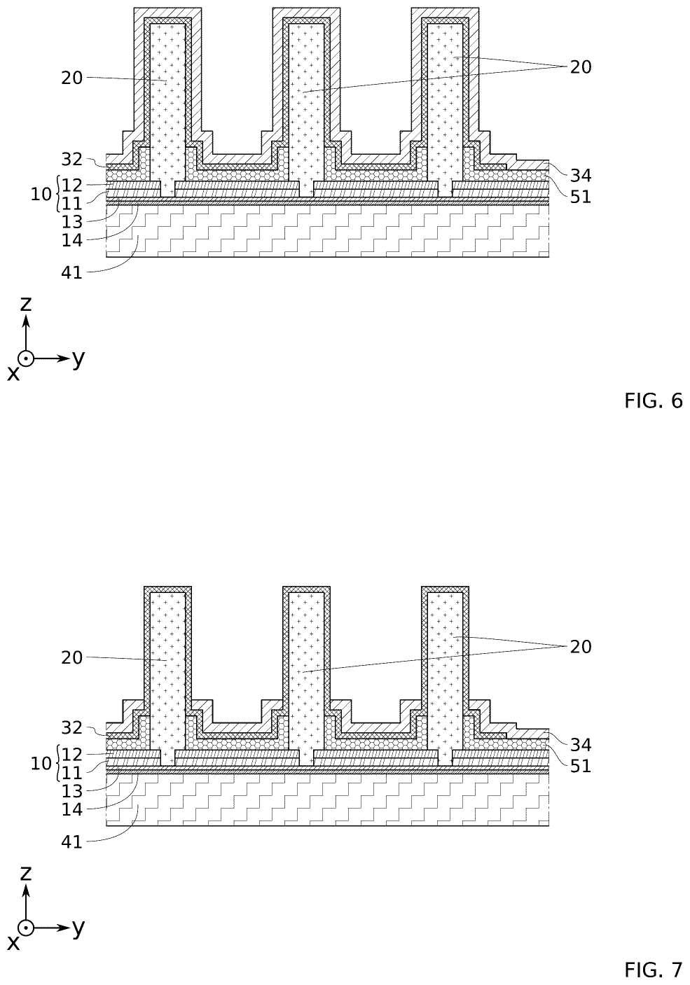

As illustrated in FIG. 6, a metal layer 34 is then deposited on the continuous layer forming the second electrical contact 32. This metal layer 34 is preferably based on a reflective metal at the wavelengths of the light emitted by the active region 22. It is typically based on aluminum.

As illustrated in FIG. 7, the metal layer 34 is then etched in part, so as to expose the subjacent continuous layer along almost all of the height of the nanowires 20. The etching typically corresponds to isotropic wet etching. After etching, the metal layer 34 is retained on the second electrical contact 32 between the nanowires 20. It can form a ring at the base of the nanowires 20. It makes it possible to form a flat electrical supply cable for the second electrical contact 32. It furthermore makes it possible to form a reflector for the light emitted by the active region 22. The light extraction efficiency of the LED is enhanced.

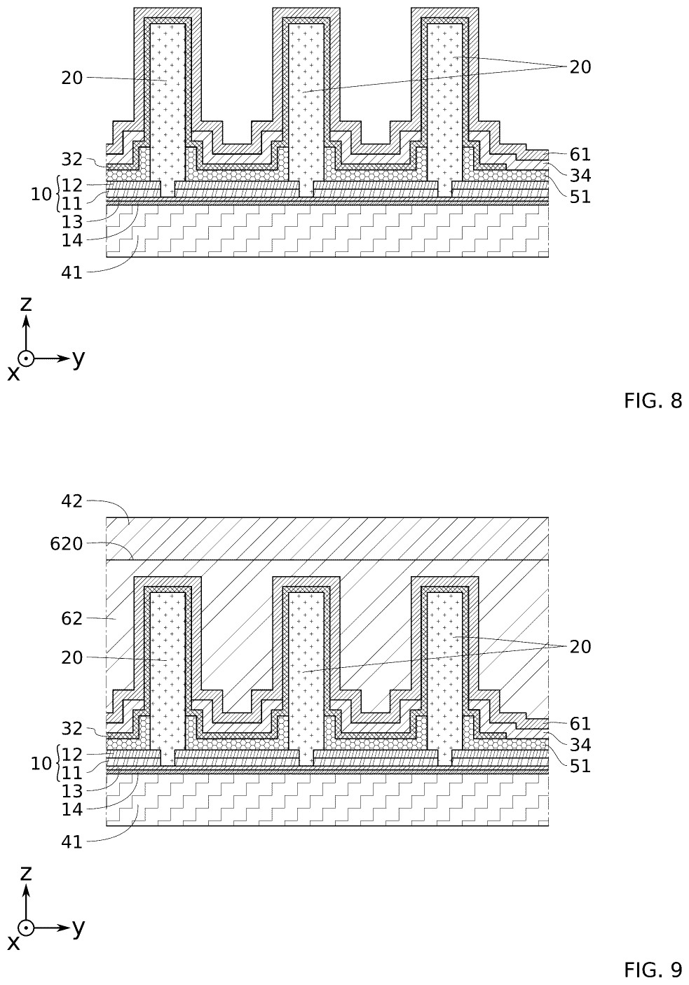

As illustrated in FIG. 8, a passivation layer 61 can then be deposited on the exposed parts of the second electrical contact 32 and on the metal layer 34. This passivation layer 61 is for example based on an aluminum alloy, for example based on Al2O3. It can be made of a dielectric material. It can be formed by plasma-enhanced chemical vapor deposition PECVD.

As illustrated in FIG. 9, the nanowires 20 protruding from the substrate 41 are then planarized by a planarization layer 62. This planarization layer 62 is typically deposited between and on the nanowires 20, then polished by chemical mechanical planarization (CMP) in order to obtain a planar surface 620 above the nanowires 20. This planarization layer 62 is typically electrically insulating and transparent.

A handling substrate 42, also referred to as “handle”, is then bonded by molecular adhesion on the flat surface 620, on the “front face”. This handling substrate 42 can be transparent, for example based on glass. In this case, it can be retained in the final device, at the end of the manufacturing method. Alternatively, the handling substrate 42 is opaque, for example based on silicon. In this case, it is typically removed at the end of the manufacturing method, after performing the steps designated for the “back face” of the device.

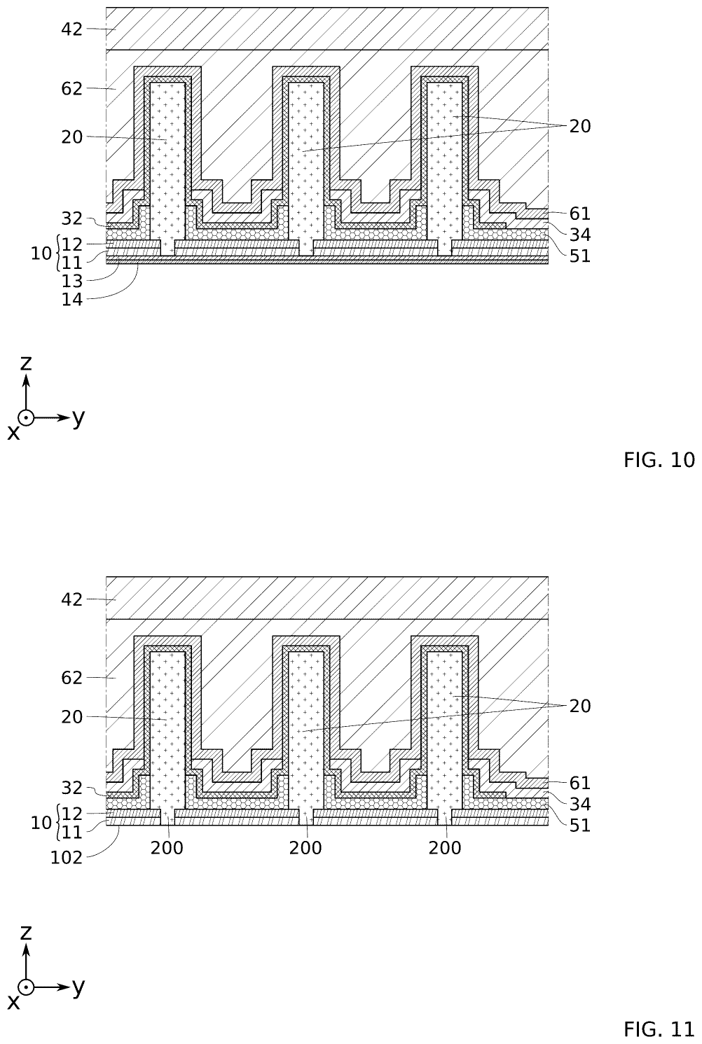

As illustrated in FIG. 10, after bonding the handling substrate 42, the growth substrate 41 is removed. This removal can be performed in a known manner by a mechanical lapping step followed by a dry etching step.

As illustrated in FIG. 11, the layers 13, 14 based on III-V materials previously used for germination/nucleation of the nanowires 20, are then removed from the back face, typically by one or more dry etchings. After removing the layers 13, 14, the bottom face 102 of the masking layer 10 is exposed. The portions 200 of nanowire 20 enclosed by the masking layer 10, initially corresponding to the seeds formed during the germination/nucleation steps, are also exposed after removing the layers 13, 14.

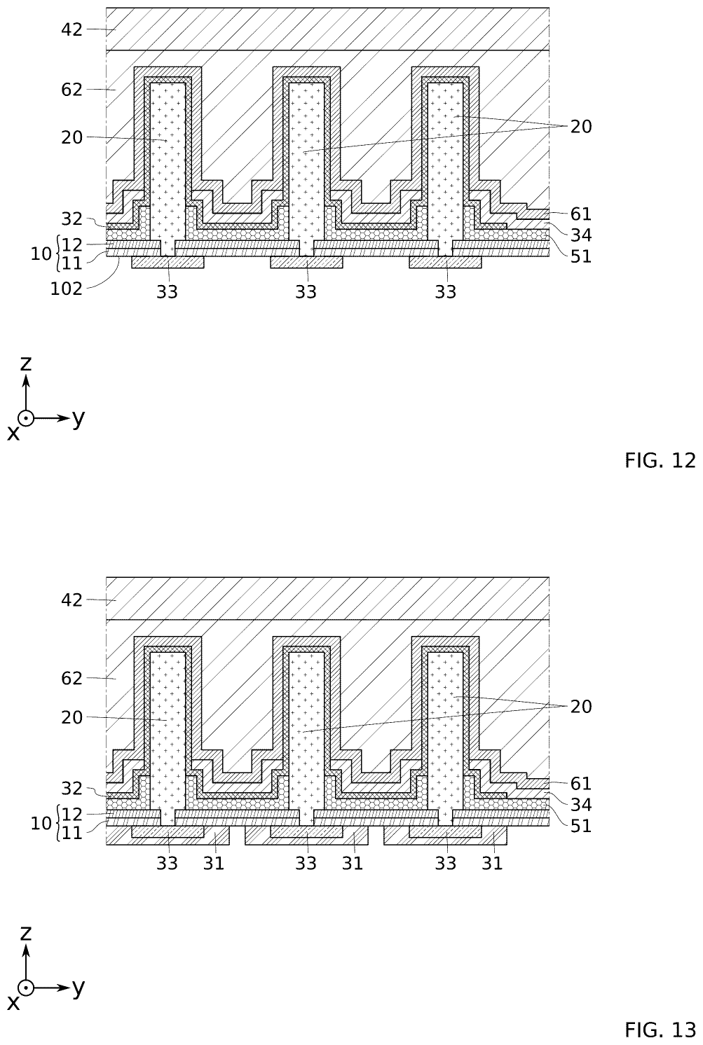

As illustrated in FIG. 12, a cobalt-doped ZnO layer is deposited on the bottom face 102 and in contact with the portions 200, then etched so as to form the pads 33 corresponding to the deceleration layers of the LED. The deposition can advantageously be carried out by various conventional physical or chemical vapor phase deposition techniques, for example by pulsed laser deposition (PLD), or by atomic layer deposition (ALD). The cobalt-doped ZnO pads 33 are advantageously ferromagnetic at ambient temperature. They also form an ohmic contact with the portions 200 of the nanowires 20. They are furthermore transparent.

As illustrated in FIG. 13, according to one possibility, the first electrical contacts 31 are formed directly on the cobalt-doped ZnO pads 33. They cover all the free surfaces of the pads 33 and bear on the bottom face 102. The first electrical contacts 31 are preferably metallic, typically based on aluminum. They indirectly provide the electrical supply of the nanowires 20, via the deceleration pads 33. The first electrical contacts 31 also form reflectors on the back face, in order to redirect the light emitted by the nanowires to the front face of the device.

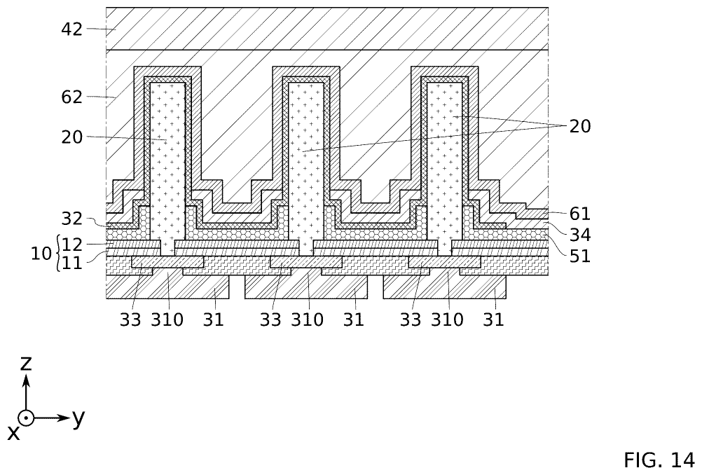

As illustrated in FIG. 14, according to another possibility, before forming the first electrical contacts 31, a dielectric layer 11 is deposited on the back face on the bottom face 102 and on the cobalt-doped ZnO pads 33. Vias 310 are then formed within the dielectric layer 11, plumb with the pads 33. The first electrical contacts 31 are then formed in pad form, on the dielectric layer 11, in contact with the previously filled vias 310. The filling of the vias 310 and the formation of the first electrical contacts 31 can be performed simultaneously in a single step.

After forming the first electrical contacts 31, the nanowire-based LED 20 can be connected on the back face, either directly to an electrical power supply or to LED control electronics, for example based on CMOS (Complementary Metal-Oxide-Semiconductor) transistor technology. The handling substrate 42 can be removed, where applicable.

The 3D LED according to the invention appears to be more efficient than a conventional 3D LED, in particular for a radial architecture. This is particularly advantageous for LED technologies operating at medium or high voltage.

The invention of not restricted to the embodiments described previously. A person skilled in the art will be able to adapt without difficulty the exemplary embodiments described above to the case of a 3D LED having an axial architecture.

1. A light-emitting diode comprising at least one three-dimensional structure comprising:
a first part having a first conductivity of a first carrier type,
a second part having a second conductivity of a second carrier type, and
an active region configured to emit or receive a light radiation of wavelength λ, said active region being interposed between the first part and the second part,
the diode further comprising:
a first electrically conducting contact configured to inject carriers of the first type into the first part, and
a second electrically conducting contact configured to inject carriers of the second type into the second part,
wherein said light emitting diode comprises a carrier deceleration layer interposed between the first contact and the first part, said deceleration layer being configured to decelerate the carriers of the first type from the first contact before being injected into the first part.

2. The diode according to claim 1, wherein the carriers of the first type are electrons and the first conductivity is N-type, the carriers of the second type are holes and the second conductivity is P-type, and the deceleration layer is an electron deceleration layer based on a diluted magnetic semiconductor material.

3. The diode according to claim 2, wherein the diluted magnetic semiconductor material is based on ZnO doped with at least one element taken from cobalt, manganese, niobium, chromium, iron, nickel, neodymium.

4. The diode according to claim 1 further comprising a masking layer having a bottom face, a top face, and openings, wherein the first part passes through the masking layer at said openings, up to the deceleration layer, the deceleration layer being in contact with the top face of the masking layer.

5. The diode according to claim 4 wherein the three-dimensional structure is obtained by localized growth through the openings of the masking layer.

6. The diode according to claim 1 wherein the 3D structure has a radial architecture such that:
the first part extends mainly along a direction z, and has edges substantially parallel to the direction z and a vertex substantially perpendicular to the direction z,
the active region comprises a radial part covering the edges of the first part, and a vertex part covering the vertex of the first part, and
the second part covers the radial part and the vertex part of the active region.

7. The diode according to claim 6, wherein the radial part forms at least 80% of the active region, and wherein the deceleration layer extends transversely to said radial part.

8. The diode according to claim 7 wherein the first part and the deceleration layer have a common interface which extends in a plane substantially perpendicular to the direction z.

9. The diode according to claim 1, wherein the 3D structure has an axial architecture forming a stack along a direction z such that:
the first part has edges substantially parallel to the direction z and a vertex substantially perpendicular to the direction z,
the active region covers only the vertex of the first part, and has edges substantially parallel to the direction z plumb with the edges of the first part, and a vertex substantially perpendicular to the direction z, and
the second part covers only the vertex of the active region, and has edges substantially parallel to the direction z plumb with the edges of the active region.

10. The diode according to claim 1 further comprising a blocking layer of the first carrier type interposed between the second part and the active region.

11. A method for producing a light-emitting diode comprising at least one three-dimensional structure according to claim 1, said method comprising:
forming the first part,
forming the active region by epitaxy on the first part,
forming the second part by epitaxy on the active region,
forming the second contact on the second part,
forming the deceleration layer in contact with the first part, and
forming the first contact on the deceleration layer.

12. The method according to claim 11, said method comprising:
forming the first part by epitaxy on a growth substrate, by localized growth through an opening of a masking layer disposed on said growth substrate,
forming the active region by epitaxy on the first part,
forming the second part by epitaxy on the active region, then
forming the second contact on the second part, by depositing a transparent conducting oxide layer,
depositing a planarization layer on the growth substrate, on and around the at least one 3D structure protruding from the growth substrate, so as to obtain a planar surface above the at least one 3D structure,
bonding a handling substrate on said planar surface,
removing the growth substrate so as to expose a portion of the first part through the masking layer,
forming the deceleration layer in contact with the exposed portion of the first part, and
forming the first contact on the deceleration layer.

13. The method according to claim 12, wherein the handling substrate is based on a transparent material at the emission wavelength A of the light-emitting diode.

14. The method according to claim 12, wherein the deceleration layer is structured in the form of a pad, and the first contact is formed on and around said pad, bearing on a lower face of the masking layer.

15. The method according to claim 12 further comprising, after forming the deceleration layer, depositing a dielectric layer on the deceleration layer, then etching a via through the dielectric layer opening onto a face of the deceleration layer, and forming the first contact through said via.

16. The method according to claim 11, wherein the formation of the first and second parts, and the formation of the active region, are performed by metalorganic vapor-phase epitaxy.
